(19) United States
(12) Patent Application Publication
(10) Pub. No.: US 2003/0034517 A1
(43) Pub. Date: Feb. 20, 2003

(54) STRUCTURE OF SPLIT-GATE EEPROM MEMORY CELL

(76) Inventor: Bin-Shing Chen, Hsinchu (TW)

Correspondence Address: Niro, Scavone, Haller & Niro, Suite 4600, 181 West Madison Street, Chicago, IL, 60602-4515, US

(21) Appl. No.: 09/769,576

(22) Filed: Jan. 25, 2001

(30) Foreign Application Priority Data
Nov. 6, 2000 (TW) 89120959

(51) Int. Cl. H01L 21/8238; H01L 29/788

(52) U.S. Cl. 257/315; 438/201

(57) ABSTRACT

A method for producing a self-aligned split-gate EEPROM memory cell is provided. The memory cell has a cell size smaller than the traditional spilt-gate structure without sacrificing program disturb immunity. Moreover, the problem current of the memory cell is much lower than the stack-gate structure. The method includes steps of: providing a silicone substrate, forming a select gate on the silicone substrate, growing a tunnel oxide layer on exposed surfaces of the silicon substrate, forming a floating gate self-aligned to one side of the select gate, performing an ion implantation to form a source region and a drain region on the silicone substrate, and forming a control gate over the floating gate and the select gate, wherein the control gate, the floating gate and the select gate are insulated from one another.

### FIELD OF THE INVENTION

The present invention relates to a method for manufacturing a split-gate EEPROM memory cell and the structure formed thereby, and more particularly to a method for manufacturing a split-gate EEPROM memory cell by a self-aligned process and the structure formed thereby.

### BACKGROUND OF THE INVENTION

In the semiconductor industry, the widely used Electrically Erasable Programmable Read-Only Memory (EEPROM) is usually classified as a non-volatile memory device because it can retain the stored data without periodic refreshing. Flash memory cell is one of the rapidly developed EEPROM memory devices.

Typically, the structure of non-volatile memory device has two basic types of structure: a stack gate structure and a split gate structure.

The EEPROM memory device having a stack gate structure usually includes a floating gate and a control gate, wherein the control gate is disposed directly above the floating gate. The memory device having the stack gate structure generally has an over-erased problem. If a memory cell in the memory array architecture is over-erased, an undesirable leaking current will occur during the read operation of the other memory cells. However, the EEPROM memory device having the split gate structure includes a control gate, a floating gate and an additional gate known as a select gate, wherein the control gate is also disposed above the floating gate, but these two are laterally offset.

The process for manufacturing a stack-gate memory cell is generally simpler than that having a split-gate structure. However, a stack-gate cell has an over-erase problem which a split-gate cell does not have, thereby the memory cell having the split-gate structure of memory cell is widely used. Although the split-gate memory cell has no over erase problem, the formation of the additional gate, i.e. the select gate, involves the problems of complex processing steps and the increasing size. The split-gate memory cell is generally larger than the stack-gate memory cell. The split-gate memory cell is difficult to scale down because the select gate and/or the control gate is not self-aligned to the floating gate.

Accordingly, a need exists in the industry for overcoming the above drawbacks.

### SUMMARY OF THE INVENTION

It is an object of the present invention to provide a method for manufacturing a spilt-gate EEPROM memory cell, wherein the floating gate is self-aligned to one side of the select gate.

The method according to the present invention includes the steps as follows:

First, a silicone substrate is provided and a select gate is formed on the silicone substrate. Then, a tunnel oxide layer is grown on the silicon substrate, and a floating gate is formed and self-aligned to one side of the select gate. Finally, a source region and a drain region is formed on the silicone substrate by performing an ion implantation and a control gate is formed over the floating gate and the select gate, wherein the control gate, the floating gate and the select gate are insulated from one another.

It is another object of the present invention to provide a method for manufacturing a spilt-gate EEPROM memory cell and the structure formed thereby.

The method according to the present invention includes the steps (a) providing a substrate and depositing a first dielectric layer thereon, (b) forming a first conductive layer and a second dielectric layer in sequence on the first dielectric layer, (c) applying a first mask and etching process on the second dielectric layer and the first conductive layer to form a select gate, (d) forming a third dielectric layer on the first dielectric layer, the second dielectric layer and the select gate, (e) applying a first anisotropic etching process on the third dielectric layer to form a sidewall beside the select gate, (f) removing the first dielectric layer is to expose the silicone substrate, (g) growing a tunnel oxide layer over the exposed surfaces of the silicon substrate, and then forming a second conductive layer on the tunnel oxide layer, the sidewall and the select gate, (h) applying a second anisotropic etching process on the second conductive layer to form a spacer adjacent to the sidewall beside the select gate, (i) applying a second photolithography and etching process on the spacer strip the spacer uncovered by a photo-resistance and, subsequently forming a floating gate self-aligned to one side of the select gate, (j) forming a fourth dielectric layer on the tunnel oxide layer, the select gate, the sidewall and the floating gate, (k) performing an ion implantation to form a source region and a drain region on the silicone substrate, (l) forming a third conductive layer on the fourth conductive layer, and (m) applying a third photolithography and etching process to form a control gate, wherein the control gate and the floating gate is separated by the fourth dielectric layer.

The tunnel oxide layer is formed by performing a thermal oxidation process. Preferably, each of the first dielectric layer, the second dielectric layer, the third dielectric layer and the fourth dielectric layer is one selected from a group consisting of silicon oxide, silicon nitride and silicon oxide/nitride composite. Certainly, the first conductive layer can be one selected from a group consisting polysilicon, amorphous silicon, recrystallized silicon and polycide. And each of the second conductive layer and the third conductive layer is one selected from a group consisting polysilicon, amorphous silicon and recrystallized silicon. Preferably, each of the first anisotropic etching process and the second anisotropic etching process is a dry etching process.

It is another object of the present invention to provide a structure of an Electrically Erasable Programmable Read-Only Memory (EEPROM), which includes a silicone substrate, a source/drain region, a tunnel oxide, a select gate, a floating gate and a control gate. The silicone substrate has a source region and a drain region and a tunnel oxide layer disposed thereon. The select gate is disposed over the tunnel oxide layer, wherein the select gate is defined by the conductive layer covered with a first insulated material thereon and comprises a sidewall made of a second insulated material. The floating gate is aligned to the select gate, and a third insulated material is disposed over the tunnel oxide layer, the select gate and the floating gate. The control gate is formed on the third insulated material.

Preferably, each of the first insulated material, the second insulated material and the third insulated material is one selected from a group consisting of silicon oxide, silicon nitride and silicon oxide/nitride composite. The conductive layer is preferably selected from a group consisting of polysilicon, amorphous silicon, recrystallized silicon and polycide. Each of the floating gate and the control gate is one selected from a group consisting of polysilicon, amorphous silicon and recrystallized silicon.

The objects and advantages of the present invention will become more readily apparent to those ordinarily skilled in the art after reviewing the following detailed description and accompanying drawings, in which:

### BRIEF DESCRIPTION OF THE DRAWINGS

FIGS. 1(a)-(m) are the schematic view showing the process for manufacturing a split-gate EEPROM flash memory cell according to the preferred embodiment of the present invention;

FIG. 2 is the schematic view showing the structure of split-gate EEPROM according to the present invention; and

FIG. 3 is a NOR-type EEPROM array according to the present invention.

### DETAILED DESCRIPTION OF THE PREFERRED EMBODIMENT

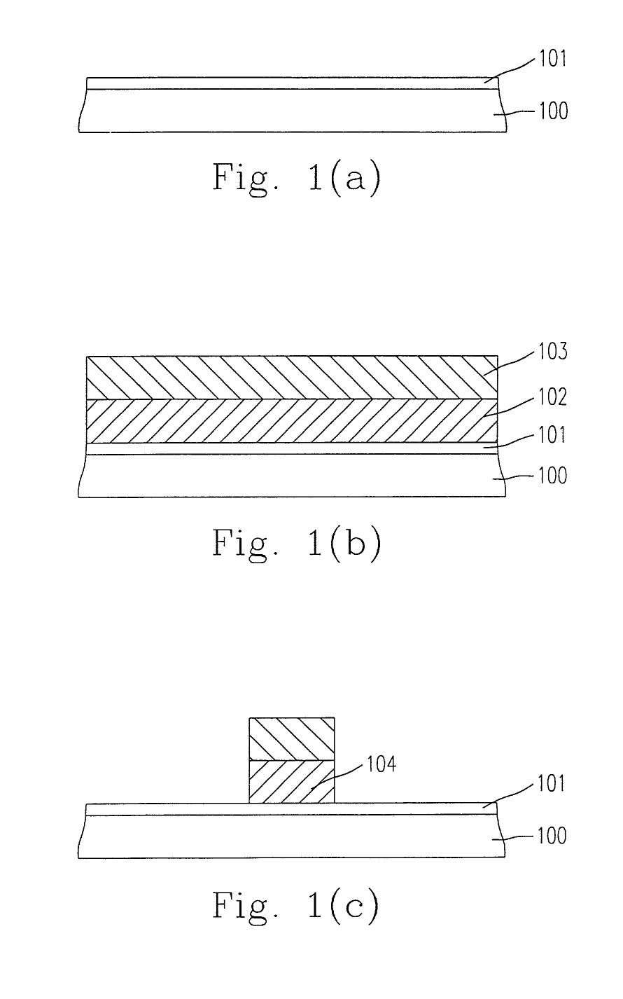

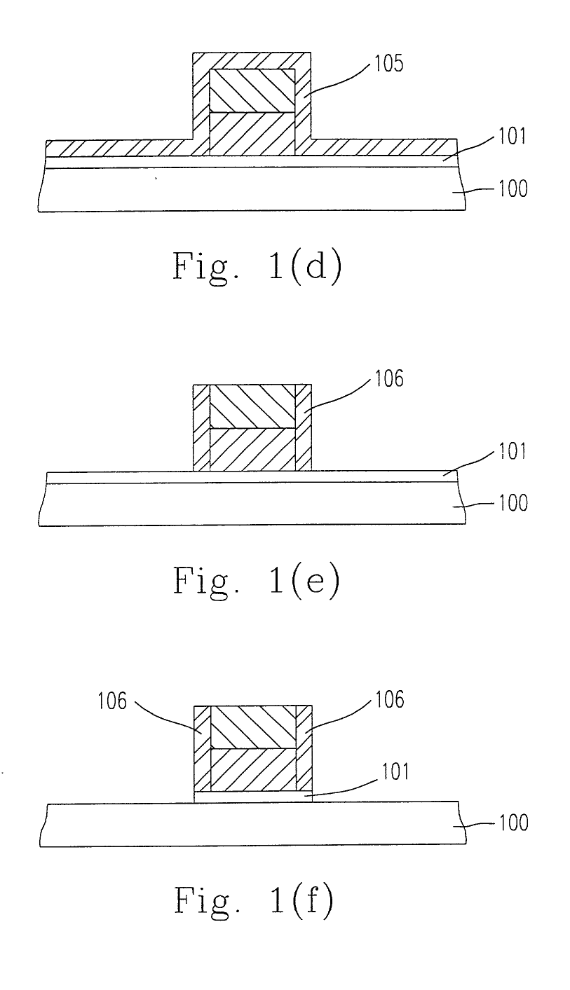

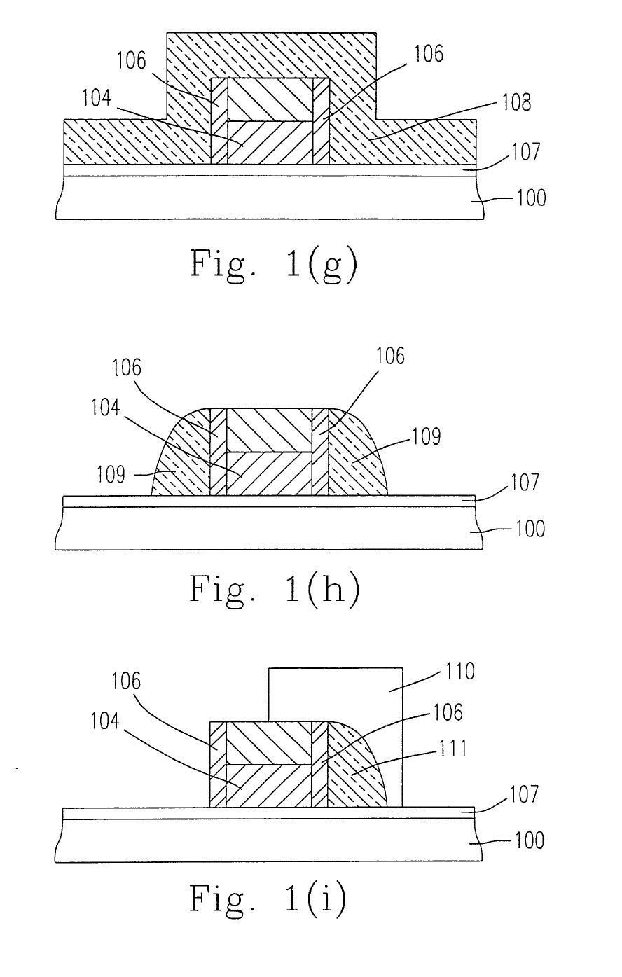

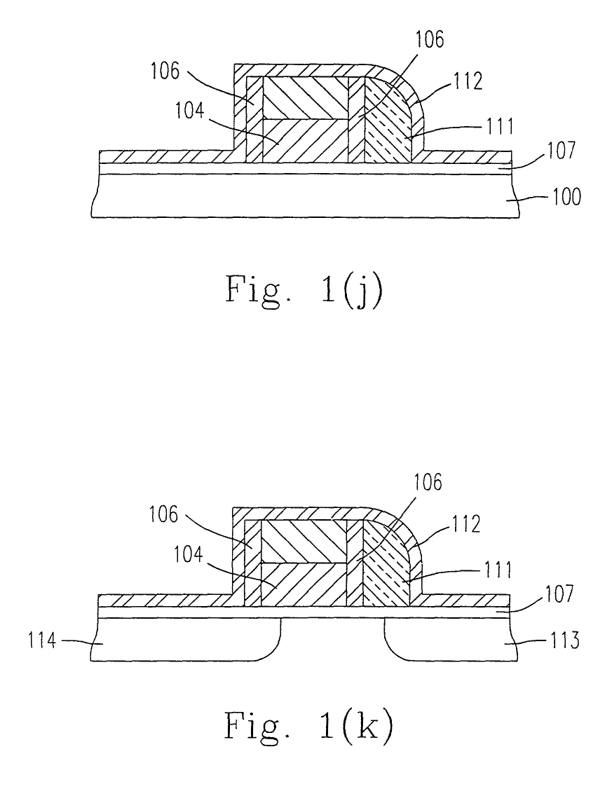

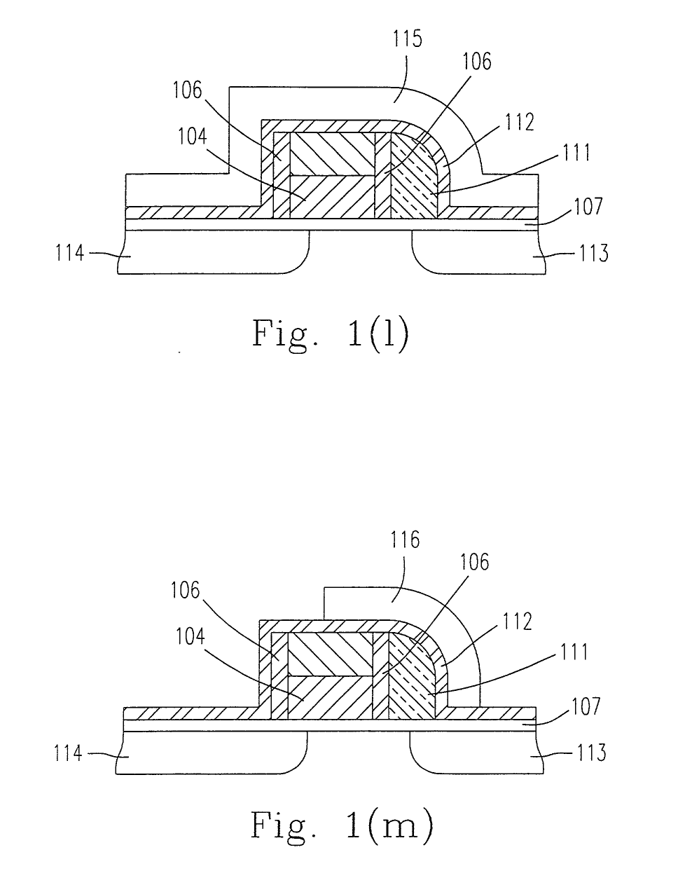

Referring to FIG. 1(a), a silicon substrate 100 is provided and a first dielectric layer 101 is formed thereon. The first dielectric layer 101 can be made of silicon oxide, silicon nitride or silicon oxide/nitride composite.

Then, a first conductive layer 102 and a second dielectric layer 103 are in sequence formed on the first dielectric layer 101, as can be seen in FIG. 1(b). The first conductive layer 102 can be made of polysilicon, amorphous silicon, recrystallized silicon or polycide. The second dielectric layer 103 can be made of silicon oxide, silicon nitride, silicon oxide /nitride composite or other insulating materials.

Referring to FIG. 1(c), the second dielectric layer 103 and the first conductive layer 102 is applied a first photolithography and etching process to form a select gate 104.

FIG. 1(d) is a schematic view showing the deposition of a third dielectric layer 105 on the first dielectric layer 101, the second dielectric layer 103 and the select gate 104. The third dielectric layer 105 can be made of silicon oxide, silicon nitride or silicon oxide/nitride composite.

Subsequently, the third dielectric layer is applied a first anisotropic etching process, such as a dry etching process, to form a sidewall 106 beside the select gate 104, as can be seen in FIG. 1(e).

In FIG. 1(f), the first dielectric layer 101 is removed to expose the silicone substrate 100.

Referring to FIG. 1(g), a tunnel oxide layer 107 is grown over the exposed surfaces of silicon substrate 100 after performing a thermal oxidation process to form a silicon oxide layer having a thickness of about 30-200 angstrom (Å), and then a second conductive layer 108 is formed on the tunnel oxide layer 107, the sidewall 106 and the select gate 104. The second conductive layer 108 can be made of polysilicon, amorphous silicon or recrystallized silicon.

The second conductive layer 108 is etched by a second anisotropic etching process to form a spacer 109 adjacent to the sidewall 106 of the select gate 104, as can be seen in FIG. 1(h).

FIG. 1(i) is a schematic view showing the spacer 109 is applied a second photolithography and etching process to strip the spacer 109 uncovered by a photo-resistance 110, and subsequently a floating gate 111 is self-aligned to one side of the select gate 104.

Referring to FIG. 1(j), a fourth dielectric layer 112 is formed on the tunnel oxide layer 107, the select gate 104, the sidewall 106 and the floating gate 111. The fourth dielectric layer 112 can be made of silicon oxide, silicon nitride and silicon oxide/nitride composite.

Then, an ion implantation is performed to form a source region 113 and a drain region 114 on the silicone substrate 100, as can be seen in FIG. 1(k).

Referring to FIG. 1(l), a third conductive layer 115 is formed on the fourth dielectric layer 112. The third conductive layer 115 can be polysilicon, amorphous silicon or recrystallized silicon.

Referring to FIG. 1(m), a third photolithography and etching process is applied to form a control gate 116, wherein the control gate 116 and the floating gate 111 is separated by the fourth dielectric layer 112.

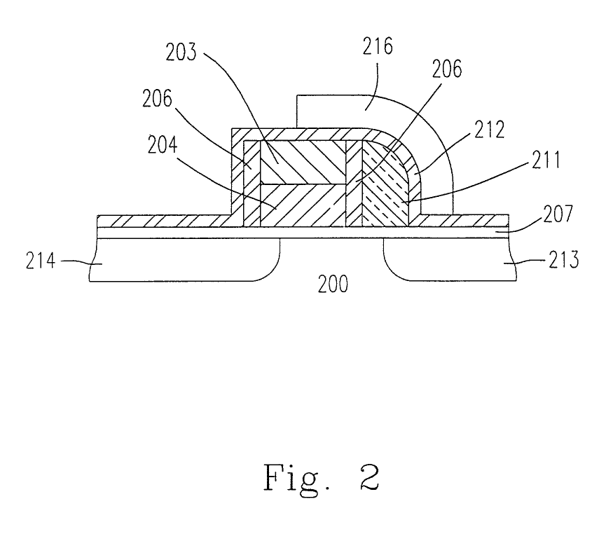

FIG. 2 is the schematic view showing the structure of split-gate EEPROM according to the present invention. The structure comprises a silicone substrate 200 having a source region 213 and a drain region 214, a tunnel oxide layer 207 disposed over the silicone substrate 200, a select gate disposed over the tunnel oxide layer 207, wherein the select gate is defined by a conductive layer 202 covered with a first insulated material 203 thereon and comprises a sidewall made of a second insulated material 206, a floating gate 211 aligned to the select gate, a third insulated material 212 disposed over the tunnel oxide layer 207, the select gate and the floating gate 211, and a control gate 116 formed on the third insulated material 212.

In this embodiment, the first insulated material 203, the second insulated material 206 and the third insulated material 212 can be made of silicon oxide, silicon nitride or silicon oxide/nitride composite. The conductive layer 202 can be made of polysilicon, amorphous silicon, recrystallized silicon or polycide. The floating gate 211 and the control gate 216 can be made of polysilicon, amorphous silicon and recrystallized silicon.

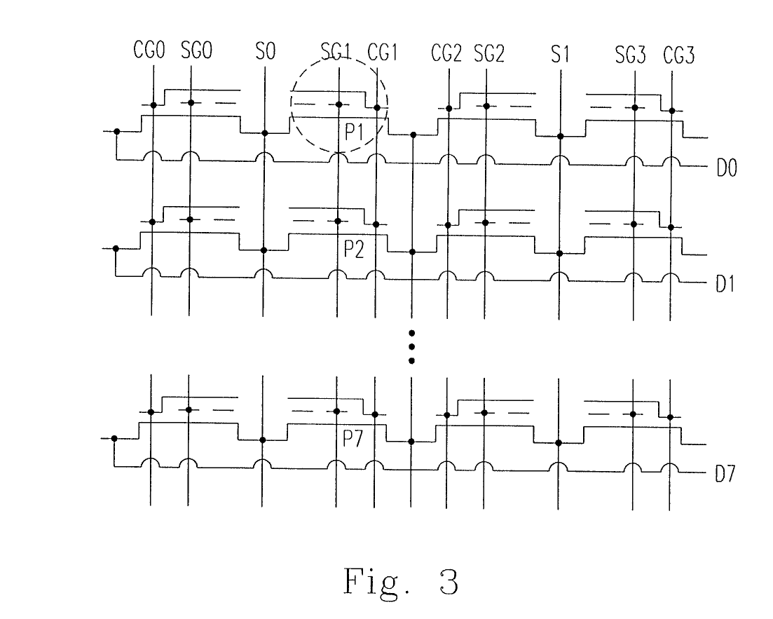

Based on the structure of the memory cell according to the present invention, a NOR-type flash EEPROM array is arranged for high speed application, as can be seen in FIG. 3.

Because the floating gate is self-aligned to the select gate, the lengths of the floating gate and the select gate can be controlled more precisely than a non-self-aligned process. Thus, the memory cell according to the present invention has a cell size smaller than the traditional split gate structure without sacrificing program disturb immunity. Moreover, the problem current of the memory cell according to the present invention is much lower than the stack-gate structure because it is programmed by using source side injection.

While the foregoing has been described in terms of preferred embodiments of the invention, it will be appreciated by those skilled in the art that many variations and modifications may be made without departing from the principles and spirit of the invention, the scope of which is defined by the appended claims.

What is claimed is:

1. A method for manufacturing an Electrically Erasable Programmable Read-Only Memory (EEPROM), comprising steps of:
providing a silicone substrate;
forming a select gate on said silicone substrate;
growing a tunnel oxide layer on exposed surfaces of said silicon
substrate;
forming a floating gate self-aligned to one side of said select gate;
performing an ion implantation to form a source region and a drain region on said silicone substrate; and
forming a control gate over said floating gate and said select gate,
wherein said control gate, said floating gate and said select gate are insulated from one another.

2. The method according to claim 1, wherein a select gate is formed by depositing a dielectric layer over a conductive layer.

3. The method according to claim 1, wherein said tunnel oxide layer is formed by performing a thermal oxidation process.

4. A method for manufacturing an Electrically Erasable Programmable Read-Only Memory (EEPROM), comprising steps of:
(a) providing a substrate and forming a first dielectric layer thereon;
(b) forming a first conductive layer and a second dielectric layer in sequence on said first dielectric layer;
(c) applying a first photolithography and etching process on said second dielectric layer and said first conductive layer to form a select gate;
(d) forming a third dielectric layer on said first dielectric layer, said second dielectric layer and said select gate;
(e) applying a first anisotropic etching process on said third dielectric layer to form a sidewall beside said select gate;
(f) removing said first dielectric layer to expose said silicone substrate;
(g) growing a tunnel oxide layer on said exposed surfaces of said silicon substrate, and then forming a second conductive layer on said tunnel oxide layer, said sidewall and said select gate;
(h) applying a second anisotropic etching process on said second conductive layer to form a spacer adjacent to said sidewall of said select gate,
(i) applying a second photolithography and etching process on said spacer to strip said spacer uncovered by a photo-resistance and, subsequently forming a floating gate self-aligned to one side of said select gate;
(j) forming a fourth dielectric layer on said tunnel oxide layer, said select gate, said sidewall and said floating gate;
(k) performing an ion implantation to form a source region and a drain region on said silicone substrate;
(l) forming a third conductive layer on said fourth conductive layer; and
(m) applying a third photolithography and etching process to form a control gate, wherein said control gate and said floating gate is separated by said fourth dielectric layer.

5. The method according to claim 4, wherein said substrate is a silicone substrate.

6. The method according to claim 4, wherein said tunnel oxide layer is formed by performing a thermal oxidation process.

7. The method according to claim 4, wherein each of said first dielectric layer, said second dielectric layer, said third dielectric layer and said fourth dielectric layer is one selected from a group consisting of silicon oxide, silicon nitride and silicon oxide/nitride composite.

8. The method according to claim 4, wherein said first conductive layer is one selected from a group consisting of polysilicon, amorphous silicon, recrystallized silicon and polycide.

9. The method according to claim 4, wherein each of said second conductive layer and said third conductive layer is one selected from a group consisting of polysilicon, amorphous silicon and recrystallized silicon.

10. The method according to claim 4, wherein each of said first anisotropic etching process and said second anisotropic etching process is a dry etching process.

11. A structure of an Electrically Erasable Programmable Read-Only Memory (EEPROM), comprising:
a silicone substrate having a source/drain region;
a tunnel oxide layer disposed over said silicone substrate;
a select gate disposed over said tunnel oxide layer, wherein said select gate is defined by a conductive layer covered with a first insulated material thereon and comprises a sidewall made of a second insulated material;
a floating gate aligned to said select gate;
a third insulated material disposed over said tunnel oxide layer, said
select gate and said floating gate; and
a control gate formed on said third insulated material.

12. The structure according to claim 11, wherein each of said first insulated material, said second insulated material and said third insulated material is one selected from a group consisting of silicon oxide, silicon nitride and silicon oxide/nitride composite.

13. The structure according to claim 11, wherein said conductive layer is one selected from a group consisting of polysilicon, amorphous silicon, recrystallized silicon and polycide.

14. The structure according to claim 11, wherein each of said floating gate and said control gate is one selected from a group consisting of polysilicon, amorphous silicon and recrystallized silicon.
